(19) United States
(12) Patent Application Publication
(10) Pub. No.: US 2014/0226293 A1
(43) Pub. Date: Aug. 14, 2014

(54) INTERFACE DEVICE

(71) Applicant: Kabushiki Kaisha Toshiba, Tokyo (JP)

(72) Inventor: Keisuke SATO, Kanagawa (JP)

(73) Assignee: KABUSHIKI KAISHA TOSHIBA, Tokyo (JP)

(21) Appl. No.: 14/176,422

(22) Filed: Feb. 10, 2014

(30) Foreign Application Priority Data
Feb. 12, 2013 (JP) 2013-024832

(51) Int. Cl. H05K 9/00; H05K 7/14

(52) U.S. Cl. CPC H05K 9/00; H05K 7/1435
USPC 361/752

(57) ABSTRACT

An interface device includes a housing, a substrate disposed in the housing, and having a first surface provided with an electrode, and a second surface disposed on a side opposite to the first surface, a first electronic component provided on the second surface of the substrate, and configured to emit electromagnetic waves, a second electronic component, configured to perform at least either transmission or reception of an electric signal, and a seal layer including a display surface disposed without overlapping the first electronic component and the second electronic component in a first direction perpendicular to the first surface of the substrate.

### CROSS-REFERENCE TO RELATED APPLICATION

This application is based upon and claims the benefit of priority from Japanese Patent Application No. 2013-024832, filed Feb. 12, 2013, the entire contents of which are incorporated herein by reference.

### FIELD

Embodiments described herein relate generally to an interface device.

### BACKGROUND

Interface devices such as memory cards may be configured to perform wireless communication with an external apparatus while connected with another external apparatus such as a host device.

### DESCRIPTION OF THE DRAWINGS

FIG. 1 is a cross-sectional view of a semiconductor device according to a first embodiment.

FIG. 2 is a plan view illustrating the internal structure of the semiconductor device shown in FIG. 1.

FIG. 3 is a plan view illustrating the external appearance (label side) of the semiconductor device shown in FIG. 1.

FIG. 4 is a plan view illustrating the external appearance (opposite side to label) of the semiconductor device shown in FIG. 1.

FIG. 5 is a cross-sectional view of the label shown in FIG. 3.

FIG. 6 is a plan view illustrating an example of attachment of the label according to another example of the first embodiment.

FIG. 7 is a plan view illustrating an example of attachment of the label according to a modified example 1-1 of the first embodiment.

FIG. 8 is a plan view illustrating an example of attachment of the label according to a modified example 1-2 of the first embodiment.

FIG. 9 is a plan view illustrating another example of attachment of the label according to the modified example 1-2 of the first embodiment.

FIG. 10 is a plan view illustrating an example of attachment of the label according to a modified example 1-3 of the first embodiment.

FIG. 11 is a plan view illustrating an example of attachment of the label according to a modified example 1-4 of the first embodiment.

FIG. 12 is a cross-sectional view of a semiconductor device according to a second embodiment.

FIG. 13 is a cross-sectional view of a semiconductor device according to a modified example of the embodiment shown in FIG. 12.

FIG. 14 is a cross-sectional view of a semiconductor device according to another modified example of the embodiment shown in FIG. 12.

FIG. 15 is a perspective view illustrating an electronic apparatus according to a third embodiment.

FIG. 16 is a plan view illustrating the inner surface of an upper cover of the electronic apparatus shown in FIG. 15.

FIG. 17 is a cross-sectional view illustrating a condition of the electronic apparatus shown in FIG. 15 to which the semiconductor device is attached.

FIG. 18 is a cross-sectional view illustrating a condition of an electronic apparatus according to a modified example of the third embodiment to which the semiconductor device is attached.

### DETAILED DESCRIPTION

In general, embodiments provide a device capable of reducing effects of extraneous radio waves.

For achieving this object, an interface device according to one embodiment includes a housing and a substrate disposed in the housing. There are provided on the substrate a first electronic component, an antenna unit performing at least either transmission or reception of radio waves, and a second electronic component electrically connected to the first electronic component. There is further provided a cover layer which includes a display surface, disposed on the surface of the housing so as to be exposed to the outside. The cover layer contains a metal component, and does not overlap the first electronic component and the second electronic component as viewed from the exposed side of the display layer in the thickness direction of the housing.

In this specification, a plurality of terms are given to some individual elements. These terms are given as examples only, and do not exclude any other terms that may be used. Also, individual elements to which a plurality of terms are not given herein may be expressed using other terms.

In addition, the respective figures referred to herein are only schematic illustrations, and the relationships between thicknesses and plane dimensions, the ratios of respective layers to other layers, or other conditions shown in the figures may be different from those conditions in actual situations. It is intended, therefore, that the specific thicknesses and dimensions be determined only through the teachings in the following description. Furthermore, the respective figures may include parts which have dimensional relationships and ratios that differ across the figures.

### First Embodiment

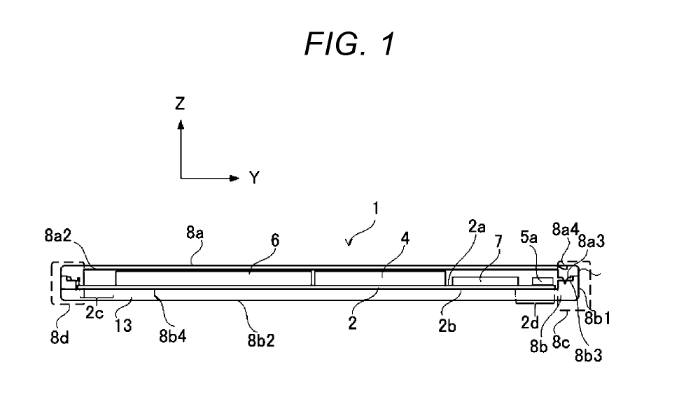

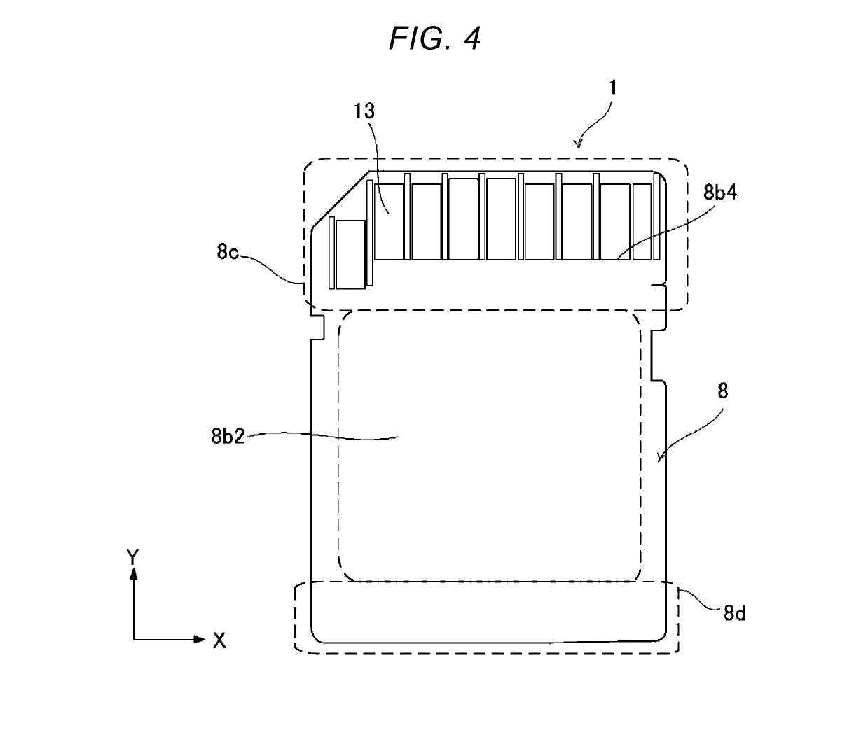

FIGS. 1 through 5 illustrate a semiconductor device 1 corresponding to an interface device according to a first embodiment. The semiconductor device 1 may be a semiconductor memory device, for example, a NAND-type flash memory. Examples of the semiconductor device 1 include card products such as micro SD cards and SD cards, memory media, media, and memory devices.

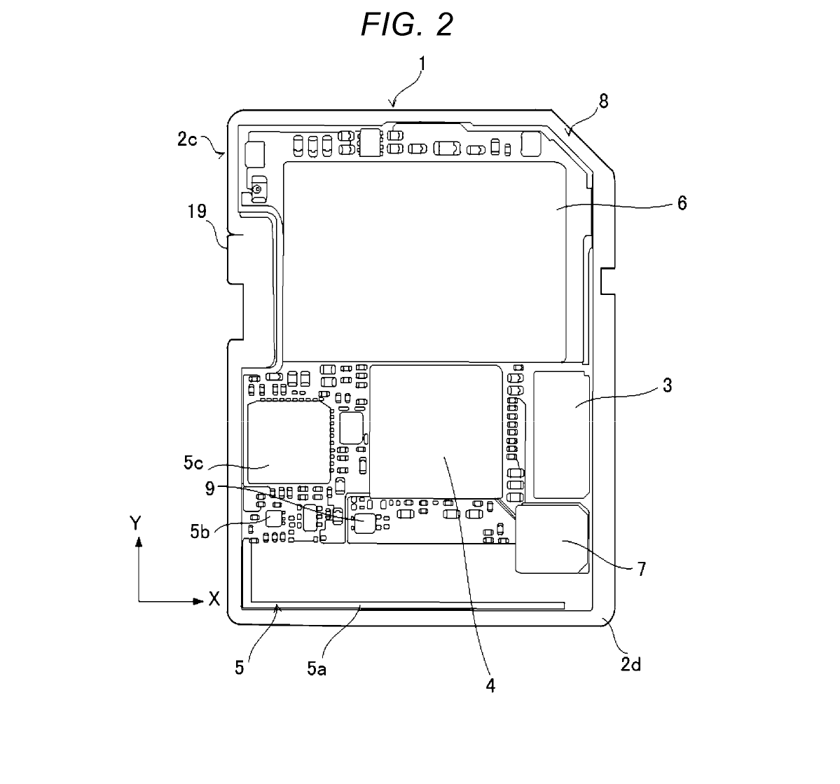

FIG. 1 is a cross-sectional view of the semiconductor device 1. FIG. 2 is a plan view illustrating the internal structure of the semiconductor device 1. As illustrated in FIGS. 1 and 2, the semiconductor device 1 includes a substrate 2, a semiconductor controller chip (referred to herein according to context as NAND controller, chip control part, first electronic component, or first control unit) 3, a wireless controller (referred to herein according to context as wireless LAN [local area network] baseband large scale integration, signal control part, second electronic component, second control unit, and first wireless processing unit) 4, an antenna unit (referred to herein according to context as second wireless processing unit, transmitter/receiver, or module including third electronic component) 5, a non-volatile semiconductor chip (non-volatile memory medium, first memory element, first semiconductor element, first semiconductor device, first semiconductor component, NAND-type flash memory, first memory, flash, or fourth electronic component) 6, a volatile semiconductor chip (volatile memory medium, second memory element, second semiconductor element, second semiconductor device, second semiconductor component, second memory, or fourth electronic component) 7, a case (referred to herein according to context as housing, cover unit, sealing member, protecting member, or resin unit) 8, and a passive component (referred to herein according to context as sixth electronic component) 9.

The case 8 according to the first embodiment includes an assembly of a first case (referred to herein according to context as first housing part, first protecting part, or first cover part) 8a and a second case (referred to herein according to context as second housing part, second protecting part, or second cover part) 8b. The case 8 is configured so as to accommodate the substrate 2, the non-volatile semiconductor chip 6, and other components inside the case 8. For example, the case 8 is made of resin (e.g., epoxy resin). The case 8 covers the substrate 2, the non-volatile semiconductor chip 6 and others. A label (referred to herein according to context as display layer, seal, third cover part, cover member, or metal film) 10 is provided on the first case 8a. The details of the label 10 will be described later.

The case 8 according to the first embodiment includes a first end 8d containing an area where an electrode unit (referred to herein according to context as external connecting terminal, interface, or connecting unit) 13 that is provided for electric connection with a host device (described later) is located, and a second end 8c disposed on the side opposite to the first end 8d and containing an area where a fitting portion (referred to herein according to context as concave portion, part of held portion, or convex portion) 8a4 to which the finger or nail of a user is fitted when the semiconductor device 1 is pulled from the host device. The semiconductor device 1 according to the first embodiment is ordinarily put into or positioned at a location electrically connected to the host device by having the first end 8d containing the electrode unit 13 be a leading end by which it is inserted into the host device, and the second end 8c be the trailing end by which it is pulled out (separated) from the host device. According to this embodiment, it is assumed that the direction of extension between the first end 8d and the second end 8c corresponds to the insertion and separation direction.

The first case 8a includes a wall disposed opposed to a first surface 2a (referred to herein according to context as first carrying surface) of the substrate 2 to cover the first surface 2a. The surface of the wall on the side opposite to the first surface 2a (referred to herein according to context as outer surface) includes an affixing portion 8a2 on which the label 10 is provided, a peripheral portion 8a3 provided around the affixing portion 8a2 and joined with the second case 8b, and a concave portion 8a4 functioning as the fitting portion discussed above.

The affixing portion 8a2 according to this embodiment includes, for example, an area whose outer surface is processed such that it is concaved toward the inside of the case 8 from the peripheral portion 8a3 in accordance with the shape of the label 10 (i.e., in conformity with the outer peripheral size), or that the roughness on the surface of the area are less than the roughness of the peripheral portion 8a3 in accordance with the shape of the label 10 (so as to allow the user to recognize a change in the sense of touch at the time of touching the surface of the case 8 as a result of a change in the roughness of the surface). This area thus formed allows identification of the affixing position of the label 10 by the sense of sight and touch, and prevents positional shift of the label 10 after fixation. The peripheral portion 8a3 in this embodiment includes a standing wall extending toward the second case 8b, for example. This standing wall facilitates attachment and junction to the second case 8b.

The concave portion 8a4 in this embodiment allows the nail of the user to easily fit to or easily pinch the semiconductor device 1 at the time of removal of the semiconductor device 1 after insertion of the semiconductor device 1 into the host device, for example. According to the case 8 of the semiconductor device 1 in this embodiment, the affixing portion 8a2 and the concave portion 8a4 are located on the same surface. Thus, the label 10 is noticeable to the user. In this structure, the label 10 enters the range of vision of the user simultaneously with the visual recognition of the concave portion 8a4 by the user when the user fits his/her finger or nail to the concave portion 8a4, for example.

The second case 8b includes a wall 8b1 disposed opposed to a second surface 2b (second carrying surface) positioned on the side opposite to the first surface 2a of the substrate 2, and covering the second surface 2b. The wall 8b1 has an outer surface area 8b2 on which the manufacturing number and the like are printed, a peripheral portion 8b3 provided around the outer surface area 8b2 and joined with the first case 8a, and an opening portion 8b4. The opening portion 8b4 in this embodiment is an area containing an open portion which communicates with the inside of the case 8 and through which the external connecting terminal 13 corresponding to the electrode unit discussed above is exposed.

The first case 8a and the second case 8b according to the first embodiment overlap each other in the thickness direction of the case 8, and bonded to each other by fusion or other methods. The thickness direction in this embodiment corresponds to the direction perpendicular to the extension direction of the display surface of the label 10 (X direction and Y direction shown in FIG. 1 and FIG. 2). For example, the thickness of the case 8 refers to the width of the extension of the case 8 in the thickness direction, and corresponds to the Z direction in FIG. 1.

The antenna unit 5 according to the first embodiment includes an antenna pattern (referred to herein according to context as transmitter, receiver, transmitter/receiver, or third electronic component) 5a, a switch (referred to herein according to context as single pole dual throw or third electronic component) 5b, and a radio frequency integrated circuit component (referred to herein according to context as radio frequency integrated circuit or third electronic component) 5c. The antenna unit 5 according to the first embodiment allows the semiconductor device 1 to transmit and receive information through wireless communication with a host device while attached and connected to another host device such as a digital camera or a personal computer, for example.

The antenna pattern 5a is a metal pattern made of copper-plating or other material that is disposed (e.g., etched, provided, or extended) along the outer periphery of the case 8. This pattern performs transmission and reception of radio waves (e.g., electromagnetic waves) (i.e., transmission of signals to the outside of the semiconductor device 1 and reception of signals from the outside of the semiconductor device 1). The switch 5b switches between transmission and reception of the signals performed by the antenna pattern 5a. The radio frequency integrated circuit component 5c is a wireless LSI for transmission and reception of radio frequency waves, and includes an integrated circuit (IC) which processes radio frequency (RF) signals.

The substrate 2 (e.g., circuit board) includes a base material made of glass epoxy resin, for example, and wiring patterns (not shown) provided on the base material. The substrate 2 has the first surface 2a, and the second surface 2b disposed on the side opposite to the first surface 2a. The first surface 2a and the second surface 2b are positioned substantially in parallel with each other, and each extend in the extension direction of the substrate 2. In other words, the first surface 2a and the second surface 2b extend in directions crossing the thickness direction of the substrate 2 (X-Y direction substantially perpendicular to the thickness direction).

The wiring patterns (not shown) are provided on the first surface 2a of the substrate 2. The external connecting terminal 13 exposed to the outside of the semiconductor device 1 is provided on the second surface 2b of the substrate 2. The substrate 2 has a first end 2c, and a second end 2d disposed on the side opposite to the first end 2c.

The external connecting terminal 13 is an interface (e.g., SD interface), and is exposed to the outside of the case 1 through the opening portion 8b4, and electrically connected with a terminal of the host device when connected with the host device. The external connecting terminal 13 in this embodiment is disposed along the first end 8d of the case 8 on the side opposed to the second end 8c along which the antenna pattern 5a is disposed. In other words, the external connecting terminal 13 is positioned on the first end 2c side as viewed from the central area of the substrate 2 (i.e., area containing the space between the non-volatile semiconductor chip 6 and the wireless controller chip 4), while the antenna pattern 5 is positioned on the second end 2d side as viewed from the central area of the substrate 2.

The base material constituting the substrate 2 is, for example, produced by stacking eight layers of base materials (e.g., synthetic resin members) (not shown) in the shape of plates (e.g., films or layers). The number of layers of the base material is not limited to eight. The wiring pattern (not shown) is formed on the surface or inside of each layer. The respective components mounted on the substrate 2 are electrically connected with each other via these wiring patterns.

As illustrated in FIGS. 1 and 2, the semiconductor controller chip 4 is attached to the first surface 2a of the substrate 2. The semiconductor controller chip 3 is positioned on the substrate 2, for example, between the non-volatile semiconductor chip 6 and the antenna pattern 5a or at least a part of the antenna pattern 5a.

The semiconductor controller chip 3 controls the operation of the non-volatile semiconductor chip 6. The semiconductor controller chip 3 writes data to the non-volatile semiconductor chip 6, reads data from the non-volatile semiconductor chip 6, deletes data contained in the non-volatile semiconductor chip 6, and perform other processing to manage the storage condition of the data within the non-volatile semiconductor chip 6, for example, according to commands from the outside (e.g., signals received from the external host device or the like).

The wireless controller chip 4 controls the operation of the antenna unit 5. The wireless controller chip 4 operates in accordance with a main clock different from the clock of the semiconductor controller chip 3.

An adhesive layer 11 (first adhesive layer) is provided between the semiconductor controller chip 3 and the first surface 2a of the substrate 2. The semiconductor controller chip 3 is fixed to the first surface 2a of the substrate 2 via the adhesive layer 11. The semiconductor controller chip 3 is electrically connected with the first surface 2a of the substrate 2 by a solder, a bonding wire, or other conductive materials.

The passive component 9 is mounted on the first surface 2a of the substrate 2 similarly to the semiconductor controller chip 3. The passive component 9 is a capacitor or a resistor, for example, but is not limited thereto. As illustrated in FIG. 2, the passive component 9 is mounted on the area of the substrate 2 surrounding the semiconductor controller chip 3 and the non-volatile semiconductor chip 6. The passive component 9 is electrically connected with the substrate 2.

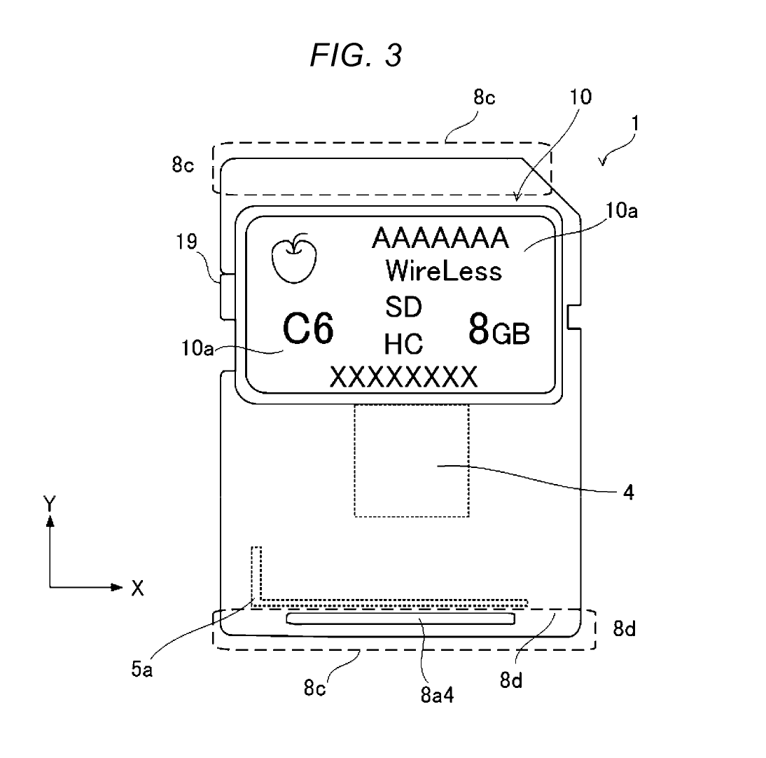

As illustrated in FIGS. 1 and 3, the non-volatile semiconductor chip 6 overlaps the substrate 2. The phase “a part overlaps the substrate” in this specification refers to the condition of the part facing the substrate in the thickness direction of the substrate (i.e., positioned inside the external shape of the substrate in the plan view), and therefore includes the condition of the part overlapping the substrate with a clearance or space left between the part and the substrate, and the condition of the part overlapping the substrate with another part interposed between the part and the substrate.

A change-over switch 19 is mounted on the semiconductor device 1 in this embodiment. The change-over switch 19 is a so-called write-protect switch which prohibits writing of information to the non-volatile semiconductor chip 6 via the foregoing external connecting terminal 13. As illustrated in FIG. 3, the condition (also referred to as, mode or status) allowing writing of information to the non-volatile semiconductor chip 6 and the condition prohibiting this writing are changed between each other by sliding the change-over switch 19 in the direction of the arrow of the Y direction.

According to the interface device in this embodiment, the label 10 is attached to the outer surface of the case 8 as illustrated in FIGS. 1 and 3. The label 10 has a display surface 10a or design surface exposed on the outer surface so that the information on the storage capacity and the manufacturer of the semiconductor device 1 can be checked with reference to the display surface 10a. According to the SD card corresponding to the semiconductor device 1 in this embodiment, information such as SD logos, memory capacity, and speed class indication is written on the label so as to visually clarify the purpose and function of the card. The structure example of the label is now described.

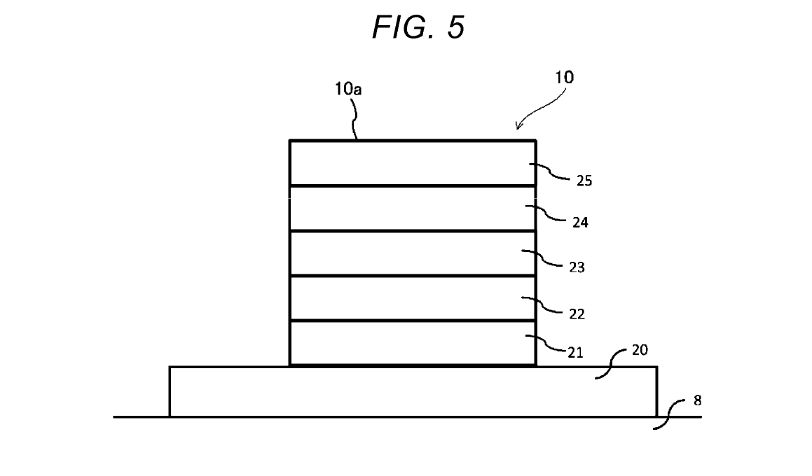

FIG. 5 illustrates an example of the label structure according to this embodiment. The label 10 is constituted by six layers of a base layer (referred to herein according to context as support layer, fourth cover member, or fourth seal portion, layer, or film) 20, an adhesive layer (referred to herein according to context as connecting portion, layer, or film) 21, a foundation layer (referred to herein according to context as metal layer, metal portion, reflection component, lustrous portion, third display layer, third cover member, or third seal portion, layer, or film) 22, a color ink layer (referred to herein according to context as second display layer, second cover member, or second seal portion, layer, or film) 23, a bonding layer (referred to herein according to context as connecting portion, layer, or film) 24, and a display layer 25 (referred to herein according to context as first display layer, first cover member, or first seal portion, layer, or film).

As illustrated in FIG. 5, the foundation layer 22 overlaps the base layer 20 via the adhesive layer 21 in this embodiment. The foundation layer 22 is constituted by a conductive metal layer (e.g., aluminum deposition layer, metal layer, or conductive layer) formed by a part containing a metal component such as aluminum. The color ink layer 23 is configured so as to transmit light. The display layer 25 has a transmission area 25a on which logos, characters and the like are formed. The transmission area 25a is configured so as to transmit light. The foundation layer 22 is a layer which contains a component capable of reflecting light such as metal and disposed and exposed at least on the surface of the foundation layer 22. The light reflected on the foundation layer 22 passes through (i.e., is transmitted through) the color ink layer 23 and the transmission area 25a to allow the information such as logos and characters displayed on the label 10 to obtain a metal luster and become visually conspicuous.

The base layer 20 supports the adhesive layer 21, the foundation layer 22, the color ink layer 23, the bonding layer 24, and the display layer 25 overlap the base layer 20. The base layer 20, the adhesive layer 21, the foundation layer 22, the color ink layer 23, the bonding layer 24, and the display layer 25 have substantially the same outer peripheral size, and are stacked in such positions that the centers of the respective layers substantially coincide with each other.

The label 10 in this embodiment is formed by aluminum deposition. The film thus formed has clearances between aluminum particles, constituting a rough film compared with foil material. This deposition method may produce the foundation layer 22 by using a small quantity of material.

The color ink layer 23 is applied to the directly upper area of the foundation layer 22 (on the side opposite to the adhesive layer 21). The color of the color ink layer 23 is not limited to one color but may include a plurality of colors. The bonding layer 24 overlaps the directly upper area of the color ink layer 23 (on the side opposite to the foundation layer 22). The display layer 25 formed by varnishing, for example, is applied to the directly upper area of the bonding layer 24 (on the side opposite to the foundation layer 22).

The condition in which a second layer is applied to the directly upper area of a first layer according to this embodiment refers to the condition in which one surface of the first layer contacts one surface of the second layer opposed to the first surface, that is, the condition in which the first layer and the second layer are stacked without any layer interposed therebetween. The expression “directly upper” means the condition in which the respective surfaces are opposed to each other when they are at the shortest distance from each other. In this case, the two surfaces contact each other when they are at the shortest distance from each other.

As illustrated in FIGS. 1 and 3, the label 10 in this embodiment is disposed without overlapping the wireless controller chip 4 and the antenna pattern 5a in the thickness direction of the case 8 (Z direction).

The condition in which the label 10 does not exist above the wireless controller chip 4 and the antenna pattern 5a refers to the condition in which a part of the label 10 and the two components of the wireless controller chip 4 and the antenna pattern 5a are not opposed to each other in the thickness direction of the case 8 (Z direction) (i.e., the label 10 and the two components of the wireless controller chip 4 and the antenna pattern 5a are positioned offset from each other when the case 8 is viewed in the Z direction), in other words, the condition in which the label 10 does not completely overlap the wireless controller chip 4 and the antenna pattern 5a in the Z direction (i.e., the label 10 does not cover the entire surfaces of the wireless controller chip 4 and the antenna pattern 5a).

When the wireless controller chip 4 and the antenna pattern 5a are completely covered by the label 10 when the case 8 is viewed in the Z direction, the receiving sensitivity at a particular wireless channel may drop. For example, the main clock of the wireless controller chip 4 in this embodiment operates at 40 MHz. When the antenna unit 5 has a wireless channel operated at a frequency close to a multiple of 40 MHz, the receiving sensitivity level of the channel may drop by interference with waves at the multiple of 40 MHz More specifically, this problem is deemed to be caused by the waves at the multiple of 40 MHz emitted from the wireless controller chip 4 and propagated to the antenna unit 5 (particularly the antenna pattern 5a), to become a noise source interfering at the time of transmission and reception of signals by the antenna unit 5.

However, the configuration in which the label 10 is disposed without overlapping the wireless controller chip 4 and the antenna pattern 5a in the Z direction as adopted in this embodiment may prevent propagation of radio waves emitted from the wireless controller chip 4 to the antenna unit 5, thereby reducing effects on the communication characteristics of the antenna unit 5 (particularly the antenna pattern 5a).

In addition, the structure in this embodiment may reduce the effect of extraneous waves transmitted to the wireless controller chip 4 as well as the adverse effect caused by the wireless controller chip 4 on other parts. According to the structure in which the label 10 not covering the electronic components such as the wireless controller chip 4 as adopted in this embodiment, the effect on the electronic components within the case 8 caused by electricity transmitted from the outside of the case 8 to the label 10 may be reduced.

As noted above, the label 10 is made of material containing a conductive metal component affixed to the outer surface of the case 8. For example, when a charged external part (such as user's finger) contacts the label 10 from the outside of the case 8, static electricity varies the potential of the metal component (e.g., foundation layer 22) within the label 10, and reaches the wireless controller chip 4 as well as causing an electrical effect.

When an overvoltage exceeding an allowable voltage for normal function and operation of circuits within the package of the wireless controller chip 4 is transmitted to the electronic components, short-circuiting may occur in a part of the circuits. According to the structure in this embodiment, the conductive layer (label 10 and foundation layer 22) provided on the outer surface of the case 8 is so disposed as not to be opposed to the electronic components such as the wireless controller chip 4 via the wall of the case 8.

Accordingly, the electronic components not desired to be affected by overvoltage, i.e., the parts having low resistance to high voltage, do not exist immediately below a part of the surface of the label 10 via the wall of the case 8 (that is, a part of the label 10 does not directly face to, via the wall of the case 8, the upper portions of the electronic components not desired to be affected by overvoltage). By adopting this structure, such a design which determines the shortest distance between the surfaces of the electronic components and a part of the surface of the label 10 may be avoided. Thus, the effect of extraneous radio waves imposed on the circuits within the electronic components through the label 10 may be reduced.

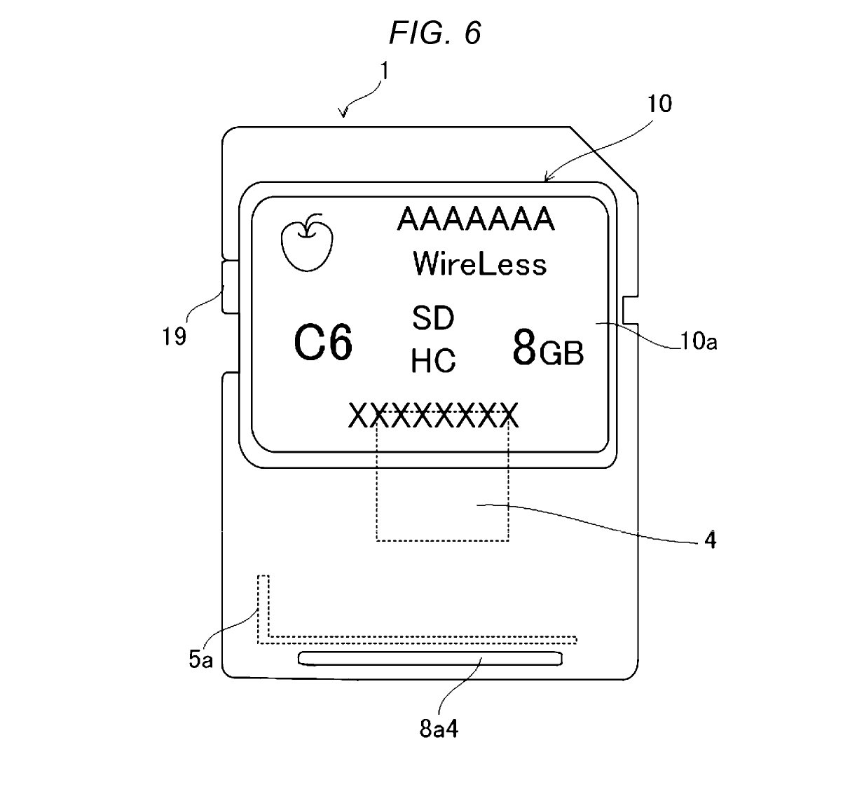

While the structure in FIGS. 1 and 3 show the condition in which the overlap between the label 10 and the components of the wireless controller chip 4 and the antenna pattern 5a is completely avoided in the Z direction, what is required herein is only a reduction of extraneous radio waves to a level within the range not affecting the operation functioning as the semiconductor device 1 (within the range allowing normal function). For example, allowable configurations include a structure which partially overlaps the label 10 with the components of the wireless controller chip 4 and the antenna pattern 5a as illustrated in FIG. 6. In this case, noise may be similarly reduced compared with the structure where the label 10 completely overlaps the components of the wireless controller chip 4 and the antenna pattern 5a. Accordingly, drop of the receiving sensitivity of the antenna unit 5 and the adverse effect on the wireless control chip 4 may be both reduced.

This embodiment may be practiced only by offsetting the label 10 from the area immediately above the electronic components such as the wireless controller chip 4 and the antenna pattern 5a, and therefore may be realized relatively easily. “Offsetting from the area immediately above” in this context refers to offsetting the entire surfaces of the electronic components facing in the direction of the label from the positions opposed to the display surface of the label 10 to positions shifted in the plane direction (X-Y direction) of the electronic components, for example.

Several examples of the structure for avoiding extraneous radio waves and excessive voltage (movement of charges) applied to the electronic components within the case 8 according to this embodiment are now discussed. It is considered that there exist two types of electrical effects on the electronic components in view of factors as sources of the effects: electrical effect caused by another part generating radio waves in accordance with operation, i.e., electrical effect from the inside of the case 8; and electrical effect generated when a charged external part contacts the label 10, i.e., electrical effect from the outside of the case 8. In the first embodiment, examples of steps taken in consideration of both the two types of effects are disclosed.

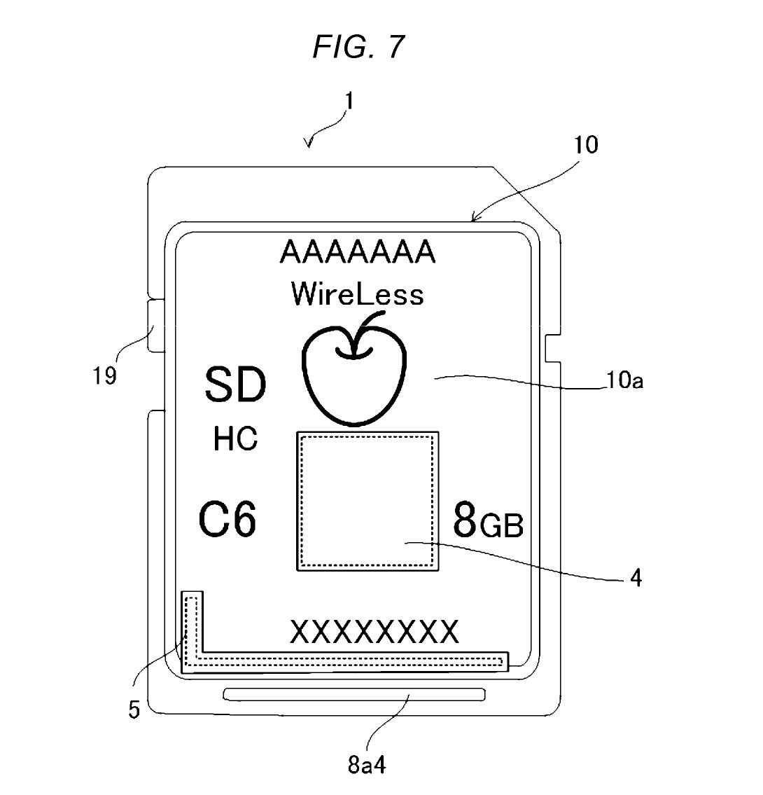

Examples including steps taken for overcoming the problem of electricity transmitted from both the inside and the outside of the case 8 are now explained with reference to FIGS. 7 through 11. In the following explanation, structures having functions identical or similar to those of the foregoing embodiment are given similar reference numbers, and the same explanation is not repeated. According to the following modified examples, there are shown the wireless controller chip 4 corresponding to an electronic component having low withstand voltage characteristics or an electronic component generating radio waves in accordance with operation, and the antenna pattern 5a corresponding to an electronic component affected by radio waves emitted from the wireless controller chip 4 for the purpose of simplifying the explanation. However, the parts having low withstand voltage characteristics, the electronic component generating extraneous radio waves, and others are not limited to those shown herein but may be replaced with alternatives for constituting a preferable embodiment.

### Modified Example 1-1

As illustrated in FIG. 7, the specific structure according to this modified example is similar to the foregoing embodiment in that the label 10 is so shaped as to avoid the area of the case 8 overlapping the antenna pattern 5a and the wireless controller chip 4 as viewed from the display surface 10a, but is different in that a part of the label 10 covers the portion surrounding this area.

As illustrated in FIG. 7, the area of the label 10 overlapping the antennal pattern 5a and the wireless controller chip 4 as viewed from the display surface 10a (Z direction) is bored. The term “bored” in this context means that an aperture is formed in the predetermined area within the label 10. According to this structure, the outer periphery (outer circumference or outer end) of the label 10 is positioned outside the antenna pattern 5a, the wireless controller chip 4, and the carrying area of the substrate 2 where these components are disposed as viewed in the Z direction as illustrated in FIG. 7.

It should be noted herein that the label 10 in this modified example is so shaped as to extend almost uniformly along the outer periphery of the case 8, and positioned such that the center of the substrate 2 and the center of the label 10 substantially coincide with each other. According to this modified example, the area of the label 10 increases, and the design of the label 10 improves. Moreover, a larger quantity of information may be written to the label 10.

### Modified Example 1-2

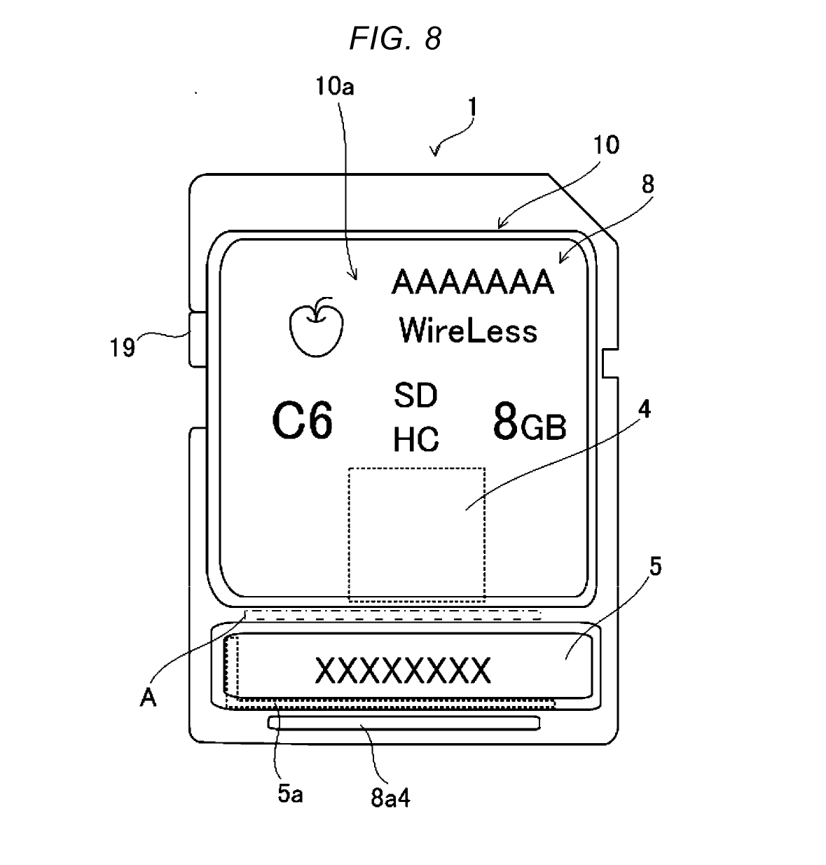

As illustrated in FIGS. 8 and 9, the specific structure in this modified example is different from the modified example 1-1 in that the label 10 covers the area of the case 8 overlapping the antenna pattern 5a and the wireless controller chip 4 as viewed from the display surface 10a.

According to the label 10 in this modified example, the entire or a part of the label 10 does not exist in an area A extending between the antenna pattern 5a and the wireless controller chip 4. The phrase “the entire or a part of the label 10 does not exist” in this context refers to the condition in which the label 10 is divided (provided as a plurality of divisions on the surface of the case 8) along the area A as the boundary such that a part of the label 10 is not positioned within the area A as illustrated in FIG. 8, for example, or the condition in which a part of the area A of the label 10 is a slit such that a part of the label 10 is not located in the area A as illustrated in FIG. 9, for example. According to this structure, the channel of electricity transmitted to the label 10 may be cut or weakened, wherefore the electrical effect given via the label 10 may be reduced.

According to the structure of this modified example, the area of the label 10 may be increased to the same size as or a larger size than the corresponding area in the modified example 1-1. Accordingly, this structure may provide not only advantages such as improvement of the design of the label 10 and increase in the quantity of information written to the label 10, but also the advantage of reducing the electrical effect from the label 10. This example may be practiced after deposition of the label 10 as well as prior to deposition.

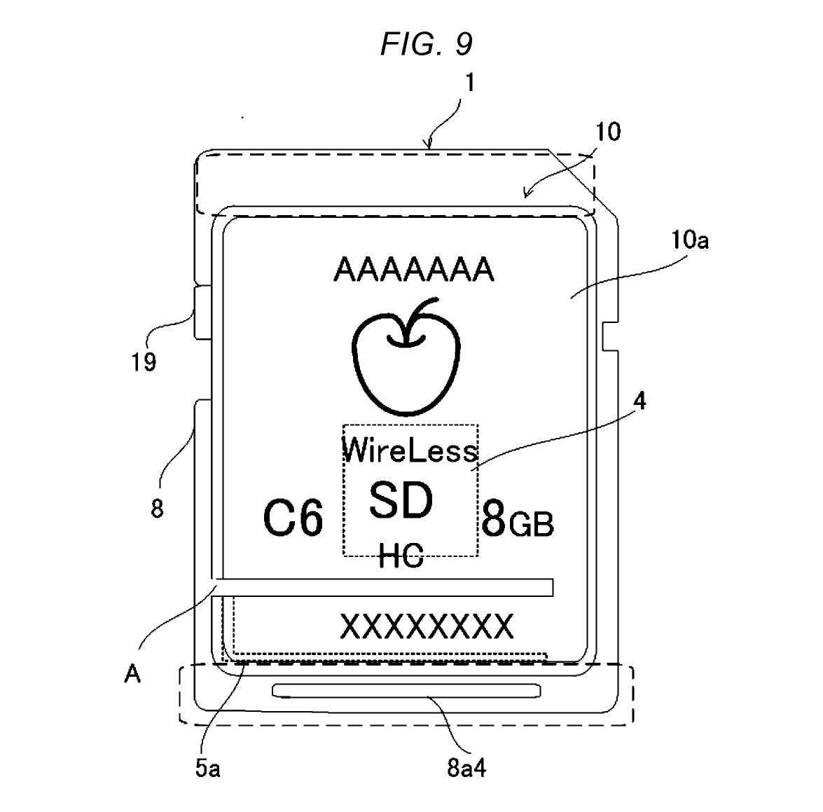

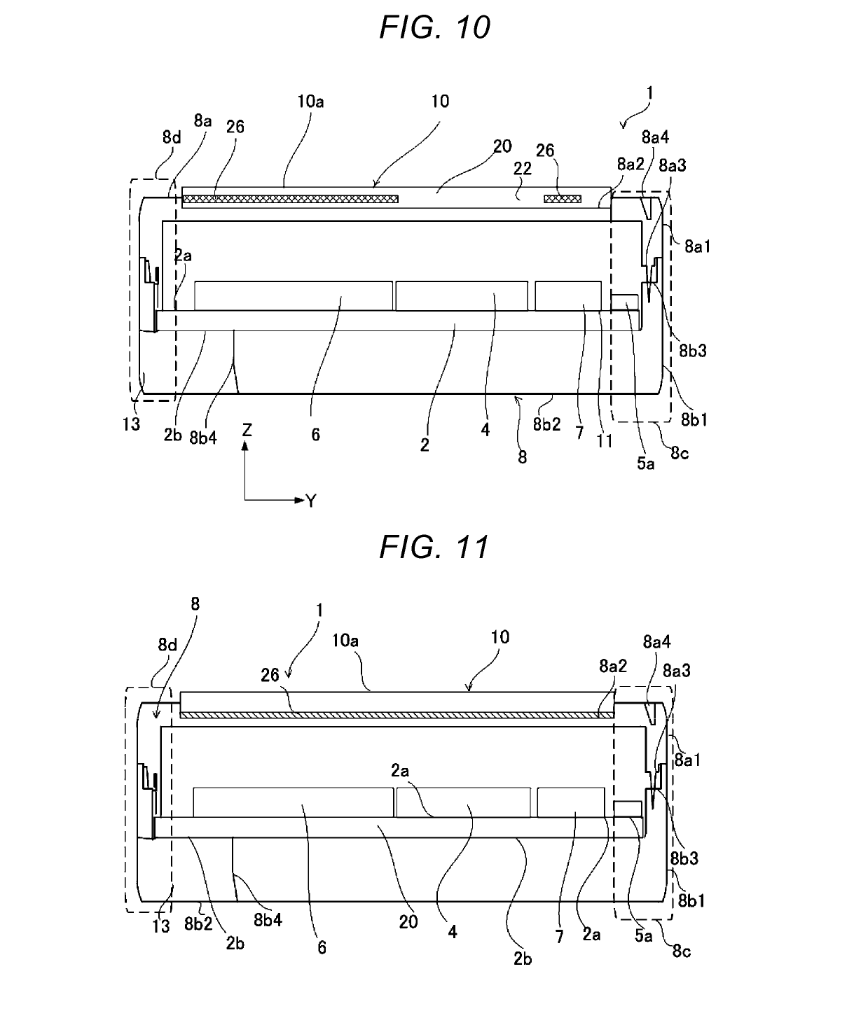

While the structure which cuts a part of the label 10 is shown in each of the modified examples in FIGS. 7 through 9, what is required herein is only a structure capable of reducing the effect of extraneous radio waves. For example, allowable configurations include a structure which removes only the metal (conductive) component contained in a part of the label 10 positioned within the area. In this case, the metal layer may be excluded only from the area of the label 10 located opposed to the antenna pattern 5a and the wireless controller chip 4. The structure in which the metal (conductive) component is removed is now explained with reference to FIG. 10.

### Modified Example 1-3

As illustrated in FIG. 10, the specific structure in this modified example is different from the foregoing embodiment in that the external appearance of the label 10 covers the area of the case 8 overlapping the antenna pattern 5a and the wireless controller chip 4 and including the area A in the Z direction.

According to the structure in this modified example, the label 10 covers the entire area including the antenna pattern 5a and the wireless controller chip 4 as well as the area A, while the foundation layer 22 within the label 10 is so designed as to reduce the effect of radio waves on the electronic components. More specifically, the foundation layer 22 has a structure similar to that of the label 10 shown in FIGS. 1 through 9, such as the structure avoiding overlap with the antenna pattern 5a and the wireless controller chip 4, the structure divided along the area containing the area A, and the structure lacking only the area A. According to this structure, the area of the foundation layer 22 as viewed in the Z direction becomes smaller than the area of the display layer 25.

The foundation layer 22 may make marks or logos lustrous when existing below the marks or logos. Thus, the design is not affected even when the foundation layer 22 is removed from portions other than the region desired to be made lustrous.

According to the structure of this modified example, the area of the external appearance of the label 10 (area of display layer 25) may be made larger than the corresponding area in the modified examples 1-1 and 1-2. Therefore, advantages such as improvement of the design of the label 10 and increase in the quantity of information written to the label 10 may be provided. Moreover, the electrical effect from the label 10 may be reduced.

### Modified Example 1-4

As illustrated in FIG. 11, the specific structure in this modified example is different in that an insulation layer (film) exists between the foundation layer 22 of the label 10 and the case 8.

According to this modified example, an insulation layer 26 exists at least in one of positions between the foundation layer 22 and the base layer 20, between the base layer 20 and the adhesive layer 21, and between the adhesive layer 21 and the case 8. The insulation layer 26 may be provided on the surface of the wall 8a1 of the case 8 facing to the first surface 2a of the substrate 2.

According to the structure in this modified example, the area of the label 10 may be increased similarly to the modified example 1-3. Thus, advantages such as improvement of the design of the label 10 and increase in the quantity of information written to the label 10 may be provided. Moreover, the electrical effect from the label 10 may be reduced.

Advantages of steps taken for overcoming the problem of electricity transmitted from the outside of the case 8 may be achieved even when the insulation layer 26 in this modified example is disposed outside the foundation layer 22 (on the side opposite to the case 8 as viewed from the foundation layer 22). In this case, the insulation layer 26 is located at least in one of positions on the front and rear sides of each layer of the color ink layer 23, the bonding layer 24, and the display layer 25.

The examples discussed herein with reference to FIGS. 1 through 11 are steps taken for overcoming the problem of electricity transmitted from both the inside and outside of the case 8. However, allowable configurations may include a structure exclusively used for avoiding the problem resulting from either the inside or the outside of the case 8.

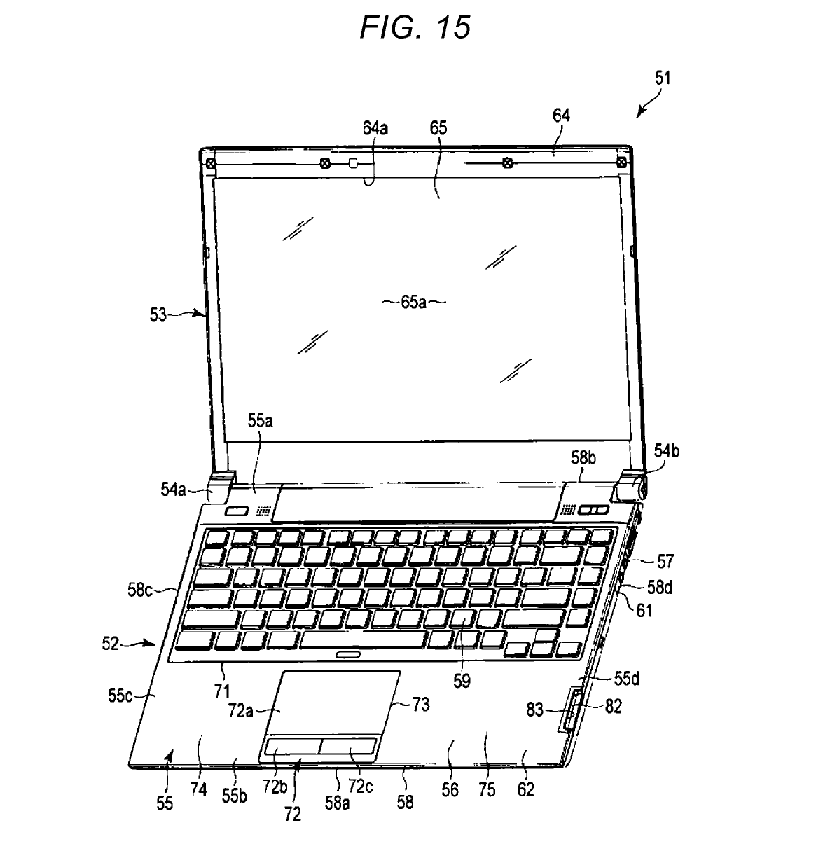

An embodiment including steps taken for overcoming the problem of electricity transmitted from the inside of the case 8 is explained with reference to FIGS. 12 through 14, while an embodiment including steps taken for overcoming the problem of electricity transmitted from the outside of the case 8 is explained with reference to FIGS. 15 through 17. In the following explanation, structures having functions identical or similar to those of the foregoing embodiment are given similar reference numbers, and the same explanation is not repeated.

### Second Embodiment

FIGS. 12 through 14 illustrate the semiconductor device 1 corresponding to an interface device according to a second embodiment. As shown in FIGS. 12 through 14, the semiconductor device 1 in this embodiment is constructed so as to overcome the problem of radio waves transmitted from the inside of the case 8. More specifically, not all of the label 10, the antenna pattern 5a, and the wireless controller chip 4 of the semiconductor device 1 are positioned together on the same first surface 2a side (or second surface 2b side) of the substrate 2. In other words, at least one of the three components of the label 10, the antenna pattern 5a, and the wireless controller chip 4 is positioned on the first surface 2a and the others on the second surface 2b of the substrate 2.

FIG. 12 shows a structure example which disposes the antenna pattern 5a on the first surface 2a of the substrate 2, and the wireless controller chip 4 on the second surface 2b of the substrate 2. According to this structure, the substrate 2 containing an insulation component exists between the label 10 and the wireless controller chip 4, wherefore movement of charges between the label 10 and the wireless controller chip 4 may be avoided even when radio waves are transmitted to the antenna pattern 5a via the label 10.

### Modified Example 2-1

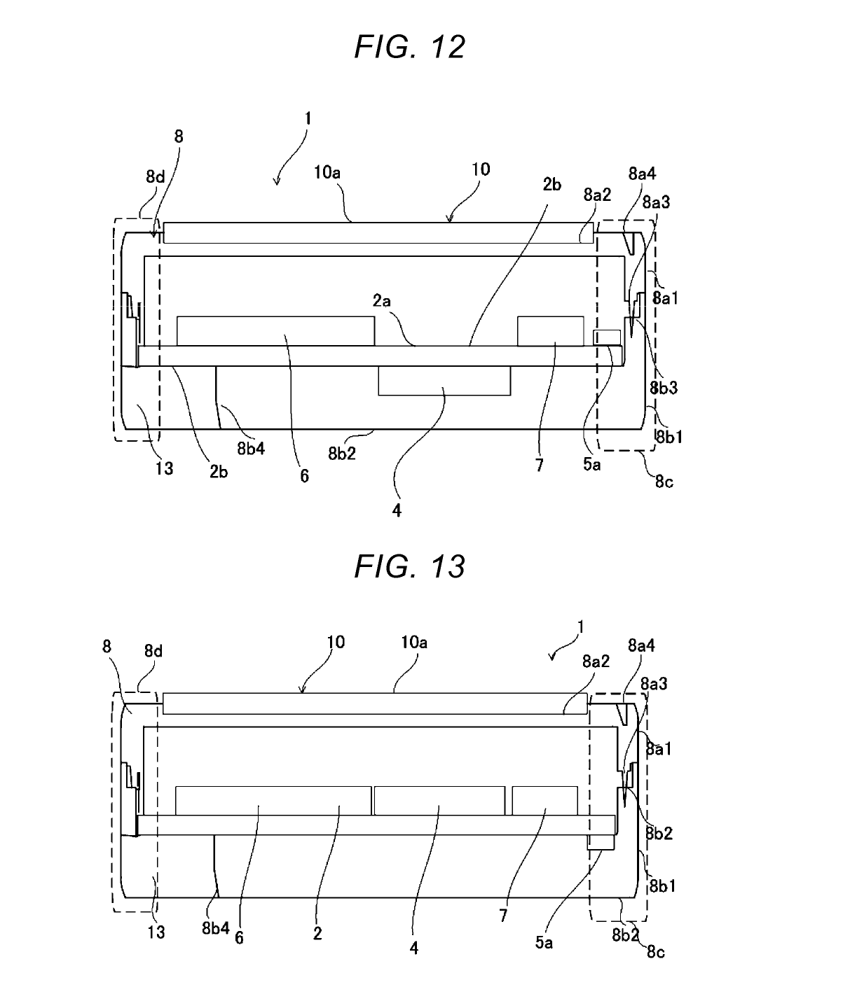

FIG. 13 illustrates a structure example in which the wireless controller chip 4 is disposed on the first surface 2a of the substrate 2, and the antenna pattern 5a is disposed on the second surface 2b of the substrate 2. According to this structure, the substrate 2 containing an insulation component exists between the antenna pattern 5a and the label 10, wherefore transmission of radio waves to the antenna pattern 5a through the label 10 may be prevented. Accordingly, advantages similar to those of the structure shown in FIG. 12 may be provided.

### Modified Example 2-2

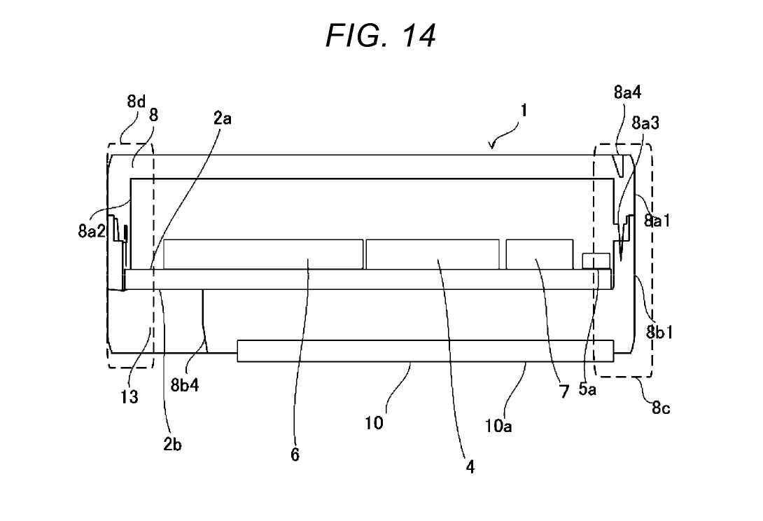

FIG. 14 illustrates a structure example in which the wireless controller chip 4 and the antenna pattern 5a are disposed on the first surface 2a of the substrate 2, and the label 10 is disposed on the wall 8a2 of the case 8 (second case 8b). In this structure, advantages similar to those of the examples shown in FIGS. 12 and 13 may be offered.

According to the structures illustrated in FIGS. 12 through 14, the shortest route of electricity transmitted in the order of the wireless controller chip 4, the label 10, and the antenna pattern 5a is not easily formed. In other words, the substrate 2 containing the insulation member is interposed at least either between the antenna pattern 5a and the label 10 or between the label 10 and the wireless controller chip 4. Thus, the electrical effect from the label 10 may be reduced.

### Third Embodiment

A third embodiment containing other solutions for overcoming the problem of electricity transmitted from the outside of the case 8 is herein described with reference to FIGS. 15 through 17. FIGS. 15 through 17 illustrate an electronic apparatus 51 corresponding to the host device referenced above. In the following explanation, structures having functions identical or similar to those of the foregoing embodiments are given similar reference numbers, and the same explanation is not repeated.

FIG. 15 illustrates the entire appearance of the electronic apparatus 51 according to this embodiment. The electronic apparatus 51 is a notebook computer, for example. The electronic apparatuses to which this embodiment is applicable are not limited to this example. This embodiment has a wide range of applicability including television receivers, cellular phones (including smart phones), tablet-type devices, and other various types of electronic apparatuses.

As illustrated in FIG. 15, the electronic apparatus 51 includes a main unit 52, a display unit 53, and hinges 54a and 54b. The main unit 52 (first unit) is a main body of the electronic apparatus on which a main board is mounted. The main unit 52 includes a first housing 55. The first housing 55 has an upper wall 56, a lower wall 57, and a circumferential wall 58, and has a flat box shape.

The lower wall 57 faces a desk surface when the electronic apparatus 51 is placed on the desk surface (external carrying surface). The lower wall 57 is positioned substantially in parallel with the desk surface. The upper wall 56 extends substantially in parallel with the lower wall 57 (i.e., substantially horizontally) with a space left between the upper and lower walls 56 and 57. A keyboard 59 is attached to the upper wall 56. The keyboard 59 is an example of an “input unit”. The input unit is not limited to a keyboard but may be a touch-panel-type input device, for example. The circumferential wall 58 rises from the lower wall 57, and connects the periphery of the lower wall 57 and the periphery of the upper wall 56.

The first housing 55 has a lower cover 61 and an upper cover 62. The lower cover 61 includes the lower wall 57 and a part of the circumferential wall 58. The upper cover 62 includes the upper wall 56 and a part of the circumferential wall 58. The first housing 55 is formed by joining the upper cover 62 to the lower cover 61.

The first housing 55 has a first end 55a to which the display unit 53 is rotatably connected, and a second end 55b located on the side opposite to the first end 55a. The circumferential wall 58 has a front wall 58a, a rear wall 58b, a left wall 58c, and a right wall 58d. The front wall 58a positioned at the second end 55b extends in the width direction (left-right direction) of the first housing 55. The rear wall 58b positioned at the first end 55a extends in the width direction of the first housing 55. Each of the left wall 58c and the right wall 58d extends in the depth direction (front-rear direction) of the first housing 55, and connect the end of the front wall 58a and the end of the rear wall 58b.

The display unit 53 (second unit) is connected with the first end 55a of the main unit 52 by the hinges 54a and 54b in such a manner as to be rotatable (openable and closable). The display unit 53 is rotatable between a closing position where the display unit 53 is laid in such a manner as to cover the main unit 52 from above, and an opening position where the display unit 53 is raised from the main unit 52.

As illustrated in FIG. 15, the display unit 53 includes a second housing 64, and a display panel 65 housed in the second housing 64. A display screen 65a of the display panel 65 can be exposed to the outside through an opening 64a formed in the front wall of the second housing 64.

As illustrated in FIG. 15, the upper wall 56 has a keyboard attachment portion 71 to which the keyboard 59 is attached, a touch pad attachment portion 73 to which a touch pad unit 72 is attached, a first palm rest 74, and a second palm rest 75. The keyboard attachment portion 71 extends in the width direction of the first housing 55 in such a direction as to be substantially in parallel with the front wall 58a and the rear wall 58b, and expands between the vicinity of the left wall 58c and the vicinity of the right wall 58d.

The keyboard attachment portion 71 is concaved toward the inside of the first housing 55 with respect to the first palm rest 74 and the second palm rest 75, allowing the keyboard 59 to be fitted to the concave. According to this structure, the upper surface of the keyboard 59 (such as key top) attached to the keyboard attachment portion 71 is positioned substantially at the same height as the upper surface of the first palm rest 74 and the upper surface of the second palm rest 75, or slightly higher than these upper surfaces.

The touch pad unit 72 is attached to the touch pad attachment portion 73. The touch pad unit 72 includes a touch pad 72a corresponding to a pointing device, and a pair of buttons 72b and 72c, for example. The touch pad attachment portion 73 is disposed between the keyboard attachment portion 71 and the front wall 58a.

The touch pad attachment portion 73 is concaved toward the inside of the first housing 55 with respect to the first palm rest 74 and the second palm rest 75 in a manner substantially similar to that of the keyboard attachment portion 71, for example, allowing the touch pad unit 72 to be fitted to the concave. According to this structure, the surface of the touch pad unit 72 attached to the touch pad attachment portion 73 is positioned substantially at the same height as the upper surface of the first palm rest 74 and the upper surface of the second palm rest 75.

In place of the foregoing structure, the touch pad attachment portion 73 may have such a structure which is not concaved with respect to the first palm rest 74 and the second palm rest 75 but is provided with an opening through which the touch pad unit 72 disposed inside the first housing 55 is exposed. In this case, the touch pad unit 72 is attached to the touch pad attachment portion 73 from the inside of the first housing 55.

As illustrated in FIG. 15, the first housing 55 has a third end 55c and a fourth end 55d each corresponding to an end of the first housing 55 in the longitudinal direction (width direction). The third end 55c includes the left wall 58c, for example. The fourth end 55d includes the right wall 58d, for example.

The first palm rest 74 and the second palm rest 75 are parts on which the hands of a user are placed during operation of the keyboard 59, for example. The first palm rest 74 and the second palm rest 75 are disposed between the keyboard attachment portion 71 and the front wall 58a. The first palm rest 74 extends between the third end 55c and the touch pad unit 72. The second palm rest 75 extends between the fourth end 55d and the touch pad unit 72.

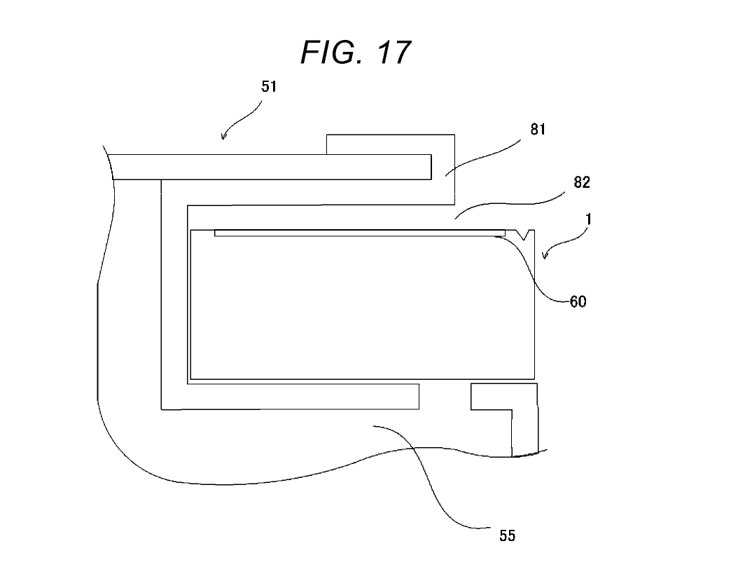

As illustrated in FIGS. 15 and 17, a card slot 81 is formed within the first housing 55. The card slot 81 is an SD card slot, for example, but may be other types of card slots. The card slot 81 faces to the inner surface of the second palm rest 75. The card slot 81 is opposed to an opening 82 opened in the circumferential wall 58 of the first housing 55. The card-shaped semiconductor device 1 is attached to and detached from the card slot 81 via the opening 82.

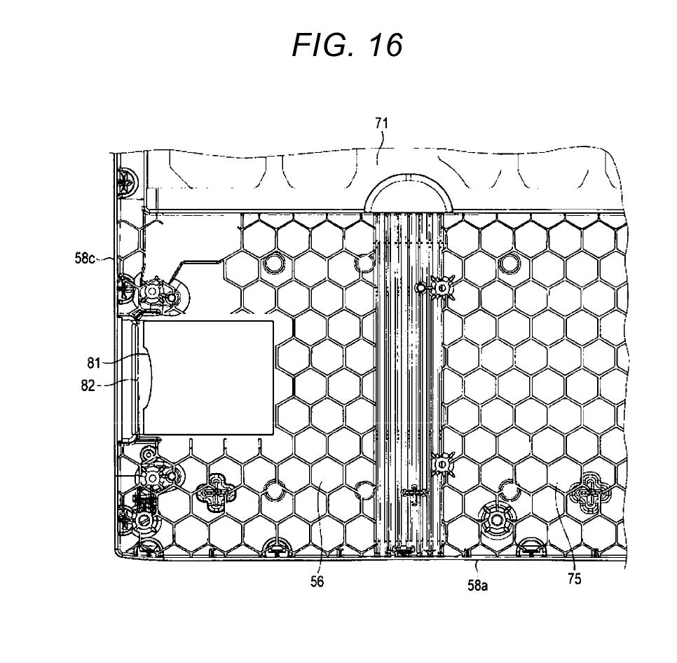

As illustrated in FIG. 15, a ground 60 is provided on a part of the first housing 55 in the vicinity of the card slot 81 (a part of the fourth end 55d, or a part of the second palm rest 75). As illustrated in FIG. 15, the ground 60 in this embodiment is disposed along the opening 82. The ground 60 is a metal frame attached to the first housing 55 along the periphery of the opening 82, for example, and is electrically connected with a conductive layer (not shown) applied to the inner surface of the first housing 55 as illustrated in FIGS. 16 and 17.

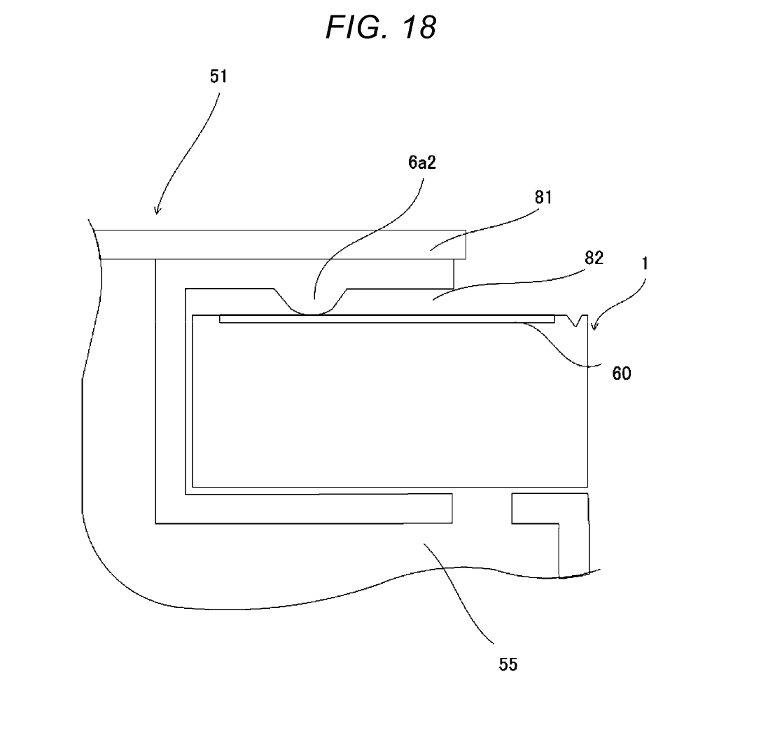

According to this structure, the finger of the user touches the ground 60 and thereby drops the potential of the finger before touching the label 10 of the semiconductor device 1 at the time of removal of the semiconductor device 1 from the card slot 81. Accordingly, the possibility that an external part charged to a high potential touches the label 10 may decrease at the time of attachment and detachment of the semiconductor device 1 to and from the card slot 81. While the structure which drops the potential of the external part touching the label 10 is discussed herein, such a structure in which electricity received from the external part via the label 10 is dispersed toward the outside of the case 8 may be adopted. According to this structure, the amount of electricity transmitted to the inside of the case 8 may be decreased. The structure which disperses electricity received from the external part via the label 10 toward the outside of the case 8 is now explained with reference to FIG. 18.

### Modified Example 3-1

FIG. 18 is a cross-sectional view of the electronic apparatus 51 which contains the semiconductor device 1 attached to the card slot 81. In the following explanation, structures having functions identical or similar to those of the foregoing embodiments are given similar reference numbers, and the same explanation is not repeated.

As illustrated in FIG. 18, a projection (referred to herein as convexity, ground, or contact depending on context) 60a is provided on an upper wall 83 of the card slot 81. The projection 60a projects (extends) to reach a position contacting the surface of the label 10 under the condition in which the semiconductor device 1 is attached to the card slot 81. The projection 60a is electrically connected with the conductive layer (not shown) applied to the inner surface of the first housing 55. According to this structure, electricity transmitted via the label 10 when the charged finger of the user touches the label 10 of the semiconductor device 1 at the time of removal of the semiconductor device 1 from the card slot 81, for example, flows to the conductive layer applied to the inner surface of the first housing 55 having a low potential. Accordingly, even when an external part charged to a high potential touches the label 10 at the time of attachment and detachment of the semiconductor device 1 to and from the card slot 81, the amount of electricity transmitted to the inside of the case 8 may be decreased.

According to the foregoing structures, deterioration of the communication characteristics and static charge resistance characteristics of the semiconductor device 1 may be avoided while providing luster for the label 10 and maintaining the design thereof similarly to the embodiments and modified examples shown in FIGS. 1 through 14.

FIGS. 1 through 17, and the structures of the respective embodiments described with reference to these figures are not limited to the specific configurations shown herein. Any of the semiconductor devices 1 according to the embodiments and modified examples shown in FIGS. 1 through 14 may be mounted on the electronic apparatus 51. For example, the electronic apparatus 51 shown in FIGS. 15 and 16 and the semiconductor shown in FIG. 1 may be combined. In addition, the configuration that overcomes extraneous waves transmitted to the label 10 may include a combination of the features of the plural embodiments and modified examples such as the structure containing divided areas and the structure containing the metal component locally existing, instead of including the feature of only one embodiment or modified example. For example, the structure dividing the label 10 may separate the label 10 in both the vertical and horizontal directions (X and Y directions) to form four equal divisions. Furthermore, the label 10 may be provided on both the upper and lower surfaces of the case 8.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An interface device, comprising:
a housing;
a substrate disposed in the housing, and having a first surface provided with an electrode;
a first electronic component disposed in the housing, and configured to emit electromagnetic waves;
a second electronic component configured to perform at least one of transmission and reception of an electric signal;
a first cover layer provided above an outer surface of a wall of the housing to which a second surface of the substrate faces, and including a light transmissive area; and
a second cover layer having a surface capable of reflecting light, including a part disposed between the transmission area and the wall, and disposed at a position without overlapping the first electronic component and the second electronic component in a first direction perpendicular to the first surface of the substrate.

2. The device according to claim 1, wherein the first cover layer has substantially the same size as that of the second cover layer, and is disposed at a position overlapping the second cover layer and not overlapping the first electronic component and the second electronic component in the first direction.

3. The device according to claim 1, wherein a part of the second cover layer is located outside an area of the first electronic component and the second electronic component as viewed along the first direction.

4. The device according to claim 1, wherein the second cover layer is smaller than the first cover layer.

5. An interface device, comprising:
a housing;
a substrate having first and second surfaces, disposed in the housing, and including an electrode;
a first electronic component provided on the second surface of the substrate;
a second electronic component provided on the second surface of the substrate;
a first seal portion covering the first electronic component from the outside of the housing; and
a second seal portion covering the second electronic component from the outside of the housing,
wherein the first seal portion and the second seal portion are substantially non-continuous.

6. The interface device according to claim 5, wherein the first seal portion is physically separated from the second seal portion.

7. The interface device according to claim 5, wherein the non-continuous portion does not overlap either the first electronic component or the second electronic component in a first direction perpendicular to the first surface of the substrate.

8. The interface device according to claim 5, wherein the first seal portion and the second seal portion each include a display layer.

9. The interface device according to claim 8, wherein the first seal portion and the second seal portion each further include a conductive layer between the display layer and the substrate.

10. The interface device according to claim 9, wherein the first seal portion and the second seal portion each further include an ink layer between the display layer and the conductive layer.

11. An interface device, comprising:
a housing;
a substrate disposed in the housing, and having an electrode;
a first electronic component provided on the substrate and configured to emit electromagnetic waves;
a second electronic component provided on the substrate, configured to perform at least one of transmission and reception of an electric signal; and
a seal portion having an outer periphery that surrounds the first and second electrical components when viewed in a thickness direction of the housing and at least one cutout in an interior region of the seal portion that is positioned above one or both of the first and second electronic components in the thickness direction.

12. The interface device according to claim 11, wherein the seal portion includes first and second cutouts, the first cutout being positioned above the first electronic component in the thickness direction and the second cutout being positioned above the second electronic component in the thickness direction.

13. The interface device according to claim 11, wherein the seal portion includes one cutout positioned above the first electronic component in the thickness direction and no cutout positioned above the second electronic component in the thickness direction.

14. The interface device according to claim 11, wherein the seal portion includes no cutouts positioned above the first electronic component in the thickness direction and one cutout positioned above the second electronic component in the thickness direction.

15. The interface device according to claim 11, wherein the seal portion includes a display layer, an ink layer between the display layer and the substrate, and a conductive layer between the ink layer and the substrate.

16. An interface device, comprising:
a housing;
a substrate disposed in the housing, and having an electrode;
a first electronic component provided on the substrate and configured to emit electromagnetic waves;
a second electronic component provided on the substrate, configured to perform at least one of transmission and reception of an electric signal; and
a seal portion that overlaps the first and second electrical components in a thickness direction of the housing,
wherein at least two of the first electronic component, the second electronic component, and the seal portion are disposed on or to face opposite sides of the substrate.

17. The interface device according to claim 16, wherein the seal portion is disposed to face a first side of the substrate and the first and second electronic components are disposed on a second side of the substrate that is opposite to the first side.

18. The interface device according to claim 16, wherein the seal portion is disposed to face and the first electronic component is disposed on a first side of the substrate, and the second electronic component is disposed on a second side of the substrate that is opposite to the first side.

19. The interface device according to claim 16, wherein the seal portion is disposed to face and the second electronic component is disposed on a first side of the substrate, and the first electronic component is disposed on a second side of the substrate that is opposite to the first side.

20. The interface device according to claim 11, wherein the seal portion includes a display layer, an ink layer between the display layer and the substrate, and a conductive layer between the ink layer and the substrate.
